(19) United States
(12) Patent Application Publication
(10) Pub. No.: US 2009/0093987 A1
(43) Pub. Date: Apr. 9, 2009

(54) Method for accurate measuring stray capacitance of automatic test equipment and system thereof

(76) Inventor: Cheng-Chin Ni, Hsin-Chu (TW)

Correspondence Address: STOUT, UXA, BUYAN & MULLINS LLP, 4 VENTURE, SUITE 300, IRVINE, CA, 92618, US

(21) Appl. No.: 11/947,594

(22) Filed: Nov. 29, 2007

(30) Foreign Application Priority Data
Oct. 5, 2007 (TW) 096137521

(51) Int. Cl. G01R 35/00; G01R 27/26

(52) U.S. Cl. 702/107; 324/658

(57) ABSTRACT

A method for measuring accurate stray capacitance of automatic test equipment (ATE) and system thereof are disclosed. The method has several steps, comprising: First of all, an internal circuit is charged and discharged several times by a driver unit; Next, the internal circuit is self-discharged, and values of voltage from V1 to V2; Then, interval of self-discharge is measured; further, the interval of self-discharge is substituted into mathematical expression of R-C discharge, and a first R-C equation is obtained; Moreover, a measuring-assistant module is connected with the ATE; Then, the steps mentioned above are repeated, and a second R-C equation is obtained; Final, stray resistance and capacitance could be solved by the two simultaneous equations. Therefore, using this method to measure stray capacitance of ATE is effective and inexpensive.

### BACKGROUND OF THE INVENTION

(1) Field of the Invention

The present invention relates to a method for measuring stray capacitance and system thereof. More particularly, the present invention relates to a method for accurate measuring stray capacitance of automatic test equipment and system thereof.

(2) Prior Art

Automatic test equipment (ATE) is used to test wafer and integral circuit. Quality of wafer or integral circuit is defined by test data which are generated by automatic test equipment. Therefore, test data are generated by test instrument which need accuracy and identification. It means that test results generated by automatic test equipment aren't changed by external environment. It also means that characteristic of one wafer or integral circuit is tested by different automatic test equipments but the same type, and the test data need to be the same. The accuracy of test result of under test device (DUT) is ensured.

Generally, automatic test equipment is consisted by complicated circuits. With time is longer, the inside of automatic test equipment would generate many kinds of resistant, inductance, and capacitance. This resistant, inductance, and capacitance are the stray resistant, stray inductance, and stray capacitance. As the automatic test equipment exists many kinds of stray resistant, stray inductance, and stray capacitance, the accuracy of test result from the automatic test equipment would be affected. The worst effect is due to the stray capacitance of automatic test equipment.

FIG. 1 shows test results of two different ATE for testing a characteristic of one DUT. There are two curves in FIG. 1, curve A (dotted line) and curve B (solid line), respectively. The curve A is a current-time curve formed by ATE A for testing an integral circuit X. The curve B is also a current-time curve formed by ATE B for testing the same integral circuit X. In FIG. 1, the curve A and the curve B are not the same curve. This means that the test results of two different ATE but the same type for testing a characteristic of an integral circuit X are different. In normal condition, the results of two different ATE but the same type for testing a characteristic of one DUT have to be the same. The curve A and the curve B have to be the same curve in FIG. 1.

However, the curve A and the curve B are not the same curve, which means that the test result tested by ATE A or ATE B are inaccuracy. The inaccuracy is due to stray capacitance formed in the automatic test equipment. After the reason of inaccuracy is known, the problem is needed to be solved. To solve the problem is to measure the stray capacitance of automatic test equipment. As the stray capacitance of automatic test equipment is found, the stray capacitance could enter to the processing unit of automatic test equipment and compensation of automatic test equipment is operated. Then, the test result tested by automatic test equipment would be accuracy. As long as the stray capacitance of automatic test equipment is found, the test results of two different ATE for testing a characteristic of one DUT would be the same. Therefore, the automatic test equipment would have an ability which could test DUT accurately.

In tradition, the method for measuring the stray capacitance of automatic test equipment comprises using vector network analyzer (VNA) or impedance analyzer. However, using this method for measuring the stray capacitance of automatic test equipment is needed to stop the automatic test equipment. Moreover, the accurate capacitance tested by VNA or impedance analyzer is also needed to know the detail of internal circuit of the automatic test equipment. Therefore, as the detail of internal circuit of automatic test equipment is unknown, the capacitance tested by VNA or impedance analyzer is still inaccuracy. Another method for measuring stray capacitance of automatic test equipment is appeared. This method is that using the charging and discharging function in the automatic test equipment to charge and discharge the automatic test equipment itself, and measure the interval of self-discharge. Substituting the measured data into mathematical expression of R-C discharge is to calculate the stray capacitance of the automatic test equipment.

However, using this method for measuring capacitance is still needed to know the stray resistant of the automatic test equipment. The stray resistant is also hard to be found. In general, the resistant is found by estimation and substituted into mathematical expression of R-C discharge to solve the stray capacitance. But, as the resistant is not accuracy, the stray capacitance is also not accuracy. Therefore, it's needed to find a method which could be easy to measure stray capacitance of automatic test equipment.

### SUMMARY OF THE INVENTION

An object of the present invention is to solve that the traditional method for measuring stray capacitance and resistance of inside of automatic test equipment is difficult and the result is inaccuracy.

To achieve the object mentioned above, the present invention provides a system for measuring accurate stray capacitance of automatic test equipment, comprising: an automatic test equipment, which is used to provide untested stray capacitance; and a measuring-assistant module, which is connected by the automatic test equipment and to solve the stray capacitance of the automatic test equipment.

Besides, the present invention further provides a method for measuring accurate stray capacitance of automatic test equipment, and the steps comprise: First at all, an internal circuit is charged and discharged several times by a driver unit; Next, the internal circuit is self-discharged, and values of voltage from V1 to V2; Then, interval of self-discharge is measured; further, the interval of self-discharge is substituted into mathematical expression of R-C discharge, Tₚ=k·ln(RC), and a first R-C equation is obtained; Final, stray resistance and capacitance could be solved by the two simultaneous equations. Therefore, stray capacitance of automatic test equipment could be obtained quickly and accurately by the effective and inexpensive method.

In the following description of the preferred embodiment, reference is made to the accompanying drawings which form a part hereof, and in which is shown by way of illustration a specific embodiment in which the invention may be practiced.

### BRIEF DESCRIPTION OF THE DRAWINGS

FIG. 1 is test results of two different ATE but the same type for testing a characteristic of one DUT.

FIG. 2 is a diagram of system of the present invention.

FIG. 3 is a diagram of equivalent circuit of system of the present invention.

FIG. 4 is a diagram of drive module of driver unit of the present invention.

FIG. 5 is a flowchart of a method for measuring accurate stray capacitance of automatic test equipment of one embodiment of the present invention.

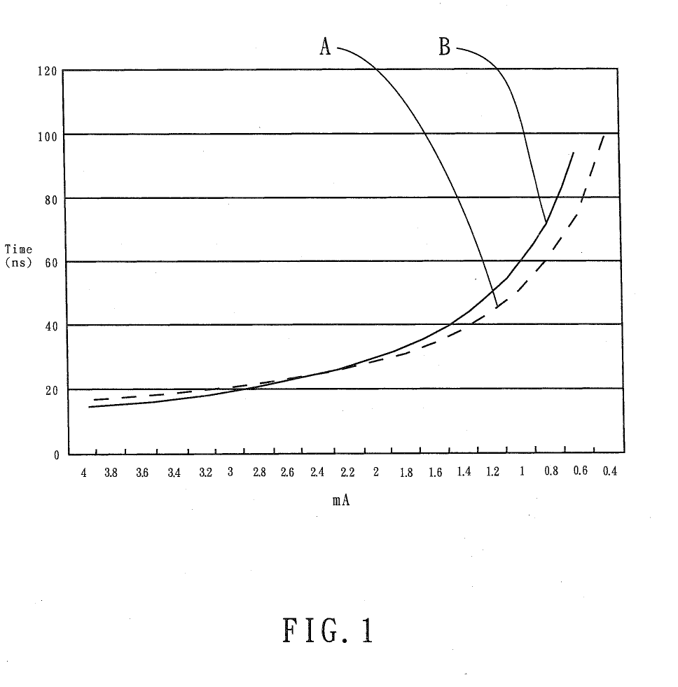

### DETAILED DESCRIPTION OF THE INVENTION

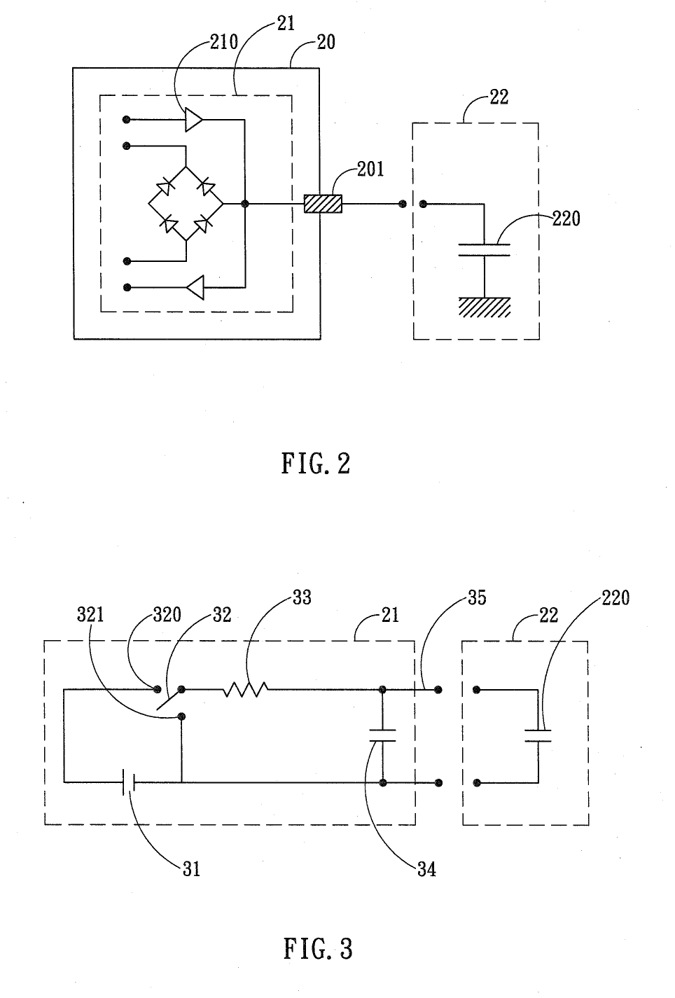

FIG. 2 shows the automatic test equipment system of the present invention. The system comprises an automatic test equipment 20 and a measuring-assistant module 22. The automatic test equipment comprises an internal circuit 21 and a signal channel 201. The signal channel 201 connects with the internal circuit 21 and is a signal I/O which connects the automatic test equipment 20 and device under test (DUT). It means that a signal from the automatic test equipment is outputted by the signal channel 201 to the DUT. Otherwise, a feedback signal from the DUT also is inputted by the signal channel 201 to the automatic test equipment 20. In one embodiment, a test signal from an automatic test equipment 20 could be outputted by a signal channel 201 to one pin of DUT, and the test signal could be read by the DUT. Then, the DUT would be tested. After testing, a feedback signal from the DUT is outputted by the pin and passes through the signal channel 201 to the automatic test equipment 20.

The internal circuit 21 of the automatic test equipment 20 further comprises a driver unit 210, which is a voltage driver device. The internal circuit 21 could be charged and discharged by the voltage driver device. The automatic test equipment 20 further comprises a processing unit, which could be used to choose the test mode of the automatic test equipment 20. The driver unit 210 could be performed different test types to the internal circuit 210 by controlling the processing unit. The different test types comprise mode 1 and mode 2. Mode 1 is that the internal circuit 21 is charged and discharged periodically in a controlled time interval. The purpose of the mode 1 is to make electricity of stray capacitance of the internal circuit 21 to normalize. It means that the electricity of stray capacitance of the automatic test equipment 20 is normalized. Mode 2 is a self-discharge mode. After the process of mode 1, the high voltage is drove by the driver unit and the internal circuit is self-discharged. The interval of self-discharge is measured and substituted into mathematical expression of R-C discharge. AR-C equation is obtained.

Moreover, the measuring-assistant module 22 is a assistant module for measuring the stray capacitance of the automatic test equipment 20. The measuring-assistant module 22 further comprises a device which could be charged and discharged. For example, the device comprises a capacitor 220, and the capacitance of the capacitor 220 is a constant which is known. Therefore, the stray capacitance of the automatic test equipment 20 could be measured by assisting of the measuring-assistant module. Detail steps of measuring method would be described later. Furthermore, the connection between the signal channel 201 and the measuring-assistant module 22 would be broken if the measuring-assistant module 22 doesn't be needed by the automatic test equipment 20.

FIG. 3 shows the equivalent circuit of the system shown in FIG. 2. The same devices have the same number in FIG. 3. A voltage source 31 of the internal circuit 21 of the automatic test equipment is the equivalent device of the driver unit 210, and resistant 33 is the equivalent device of the stray resistant of the automatic test equipment. Moreover, a switch 32 on the way of current generated by the voltage source 31 is the equivalent device which is used by computer program to control the different mode that the internal circuit 21 is performed by the driver unit 210. When the switch 32 is connected by a contact 320, the internal circuit 21 is charged and discharged by the voltage source 32. The focus point is that the capacitor 34 is charged and discharged. On the other hand, when the switch 32 is connected by another contact 321, the equivalent circuit of R-C series connection is formed. Then, the charged capacitor 320 would be self-discharged.

The equivalent device of the measuring-assistant module 22 equals to a capacitor 220. The contact 35 is the equivalent device of the signal channel 201 and a signal I/O which is connected with the measuring-assistant module 22.

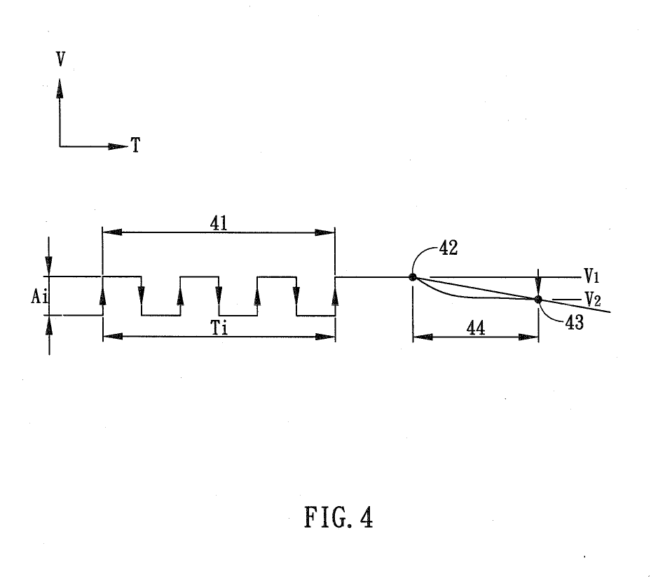

FIG. 4 shows a diagram that an internal circuit of automatic test equipment is charged and discharged by a driver unit of one embodiment of the present invention. Initial condition 41 is that the internal circuit 21 is charged and discharged periodically by driving the driver unit 210 at time Ti. The time Ti could be controlled by a processing unit of the driver unit of the automatic test equipment. Moreover, the amplification of voltage Ai and the period of the voltage also could be controlled by the processing unit. After the internal circuit 21 is charged and discharged periodically several times, the polarity of stray capacitance in the internal circuit 21 is normalized. It helps for measuring accurate value of the stray capacitance. Then, the stray capacitance of the automatic test equipment is charged and to make voltage be high voltage 42. And, the internal circuit is self-discharged. The self-discharge process is performed by nature. This time, the circuit of the automatic test equipment is an equivalent circuit of a R-C series connection shown in FIG. 3. Therefore, the result of the self-discharge would match the mathematical expression of R-C discharge, Tₚ=k·ln(RC). In this embodiment, the self-discharge process is used to find the interval 44 between the values V1 of high voltage 42 and the values V2 of low voltage 42.

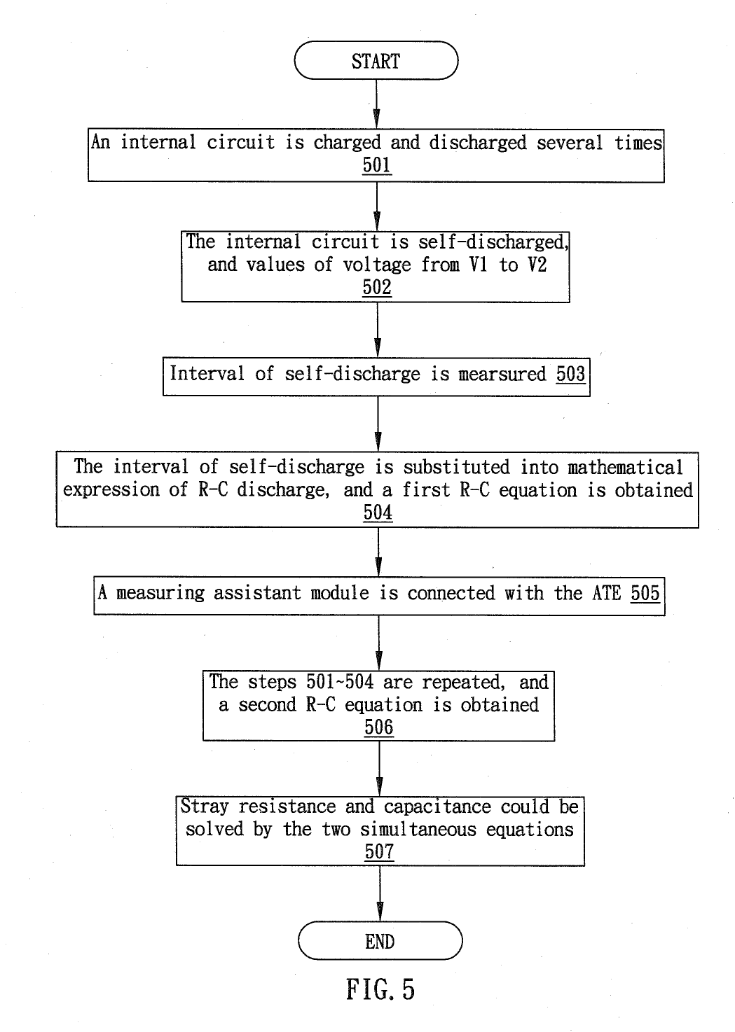

In order to describe explicitly the characteristic and spirit of the present invention, FIG. 5 shows a method for measuring stray capacitance of automatic test equipment. An embodiment accompanying FIG. 2˜4 is used to describe the method in FIG. 5.

First at all, the step 501 shows that an internal circuit 21 is charged and discharged several times. In this embodiment, the switch 32 of the internal circuit 21 is switched by a program of a processing unit of the automatic test equipment 20. The switch 32 is connected with a contact 320, and the amplification and period of voltage generated by driver unit 210 in the interval Ti are also controlled by the program. After the switch 32 is connected with the contact 320, mode 1 of driver unit 210 is performed. The internal circuit 21 is charged and discharged several times by the voltage source 31 in the interval Ti. It means that the amplification Ai of voltage in the internal circuit 21 is changed periodically by the driver unit 210 in the interval Ti. The purpose of this step is to normalize the electricity of stray capacitance of the internal circuit 21.

Step 502 shows that the internal circuit 21 is self-discharged, and the values of voltage from V1 to V2. In this embodiment, after the internal circuit 21 is charged and discharged several times, the internal circuit 21 is charged to make stray capacitance in the charged condition. Here, the switch 32 is connected with a contact 321, and the mode of driver unit 210 is performed. The internal circuit 21 is self-discharged. As shown FIG. 4, the value of voltage in the internal circuit 21 is high voltage V1 and discharged naturally to low voltage V2. Then, step 503 shows that interval of self-discharge is measured. The measurement of the interval of self-discharge could be utilized by first time which is the time that the voltage in the internal circuit is high voltage 42 and second time which is the time that the voltage in the internal circuit is low voltage 43. The interval 44 could be obtained by subtracting the value of first time from the value of second time.

Step 504 shows that the interval of self-discharge is substituted into mathematical expression of R-C discharge, and a first R-C equation is obtained. Making the obtained interval 44 in step 503 is the first interval. The mathematical expression of R-C discharge is shown by Tₚ=k·ln(RC), wherein the symbol Tₚ means the interval, the symbol k means a constant, the symbol ln means natural logarithm function, the symbol R means stray resistant of internal circuit 21, and the symbol C means stray capacitance of internal circuit 21. Therefore, the first interval is substituted into mathematical expression of R-C discharge, and the first R-C equation, Tₚ1=k·ln(RC), is obtained.

Step 505 shows that the automatic test equipment 20 is connected with the measuring-assistant module 22. In this embodiment, it's that the signal channel 201 of the automatic test equipment is connected with the capacitor 220 of the measuring-assistant module 22, as shown in FIG. 2. The automatic test equipment is connected with the measuring-assistant module, and its equivalent circuit is shown in FIG. 3. The internal circuit 21 and measuring-assistant module 22 are connected by a contact 35. The stray capacitance 34 of the internal circuit and the capacitor 220 of the measuring-assistant module 22 are series connection. Then, step 506 shows that the steps 501˜504 are repeated, and a second R-C equation is obtained. The capacitance of the capacitor 220 of the measuring-assistant module 22 is known, and used C_{know} to show. After adding a capacitor, the interval of self-discharge that the interval is measured from high voltage 42 to low voltage 43 in the internal circuit 21 would be longer. The measured interval here is second interval. The second interval is substituted into mathematical expression of R-C discharge, and a second R-C equation, Tₚ2=k·ln[R(C+C_{know})], is obtained. Here, the symbol Tₚ2 means the measured second interval, the symbol k means a constant, the symbol ln means natural logarithm function, the symbol R means stray resistant of internal circuit, the symbol C means stray capacitance of internal circuit, and the symbol C_{know} means the known capacitor 220 of measuring-assistant module.

Step 507 shows that stray resistant and capacitance could be solved by the two simultaneous equations. In step 504 and step 506, two R-C equations are obtained, which are first R-C equation and second R-C equation, respectively. The unknown elements only are the stray resistant R and stray capacitance C of the internal circuit. The accurate solutions of unknown elements are solved by two simultaneous equations and only two unknown elements. Therefore, the stray capacitance of internal circuit of automatic test equipment could be solved accurately by assisting of the measuring-assistant module. When the stray capacitance of automatic test equipment is measured, the stray capacitance could enter to the processing unit of automatic test equipment and compensation of automatic test equipment is operated. Therefore, the test result from the automatic test equipment would be accurate and believable.

The advantage of the present invention is that the connection of the signal channel of automatic test equipment and the measuring-assistant module could be broken freely by user. It doesn't affect the normal function of the automatic test equipment. Moreover, the stray capacitance of the automatic test equipment could be measured and doesn't stop the automatic test equipment. Therefore, using this method to measure stray capacitance of ATE is effective and inexpensive.

The specific arrangements and methods herein are merely illustrative of the principles of this invention. Numerous modifications in form and detail may be made by those skilled in the art without departing from the true spirit and scope of the invention.

What is claimed is:

1. A system for measuring accurate stray capacitance of automatic test equipment, including:
an automatic test equipment, which is used to provide untested stray capacitance; and
an measuring-assistant module, which is connected by said automatic test equipment and to solve the stray capacitance of said automatic test equipment.

2. The system of claim 1, wherein said automatic test equipment further comprises an internal circuit.

3. The system of claim 2, wherein said internal circuit further comprises a driver unit.

4. The system of claim 3, wherein amplification of voltage could be defined by said driver unit.

5. The system of claim 3, wherein period of voltage could be defined by said driver unit.

6. The system of claim 3, wherein said internal circuit could be charged and discharged periodically by said driver unit.

7. The system of claim 1, wherein said automatic test equipment further comprises a signaling channel, which is a signal I/O.

8. The system of claim 1, wherein said measuring-assistant module further comprises a device which could be charged and discharged.

9. The system of claim 8, wherein said device comprises a capacitance.

10. The system of claim 9, wherein said capacitance is a constant which is known.

11. A circuit for measuring accurate stray capacitance of automatic test equipment, including:
a driver unit, which is used to generate a plurality of periodical high/low voltage; and
a device which could be charged and discharged, and is connected by said driver unit;
thereby a equation could be established for obtaining stray capacitance of said automatic test equipment.

12. The circuit of claim 11, wherein amplification of voltage could be defined by said driver unit.

13. The circuit of claim 11, wherein period of voltage could be defined by said driver unit.

14. The circuit of claim 11, wherein an internal circuit of said automatic test equipment could be charged and discharged periodically by said driver unit.

15. The circuit of claim 11, wherein said device which could be charged and discharge comprises a capacitance.

16. The circuit of claim 15, wherein said capacitance is a constant which is known.

17. The circuit of claim 11, wherein said equation is a R-C equation.

18. The circuit of claim 11, wherein said circuit further comprises a signal I/O which is used to connect said driver unit with said device which could be charged and discharged.

19. A method for measuring accurate stray capacitance of automatic test equipment, comprising:
(a) an automatic test equipment is charged and discharged by itself;
(b) said automatic test equipment is self-discharged and an interval of self-discharge is measured;
(c) said interval of self-discharge is substituted into mathematical expression of R-C discharge, and a first R-C equation is obtained;
(d) a measuring-assistant module is connected by said automatic test equipment;
(e) steps (a)˜(d) are repeated, and a second R-C equation is obtained; and
(f) stray capacitance of said automatic test equipment is obtained by solving said first and second R-C equations.

20. The method of claim 19, wherein said automatic test equipment further comprises an internal circuit.

21. The method of claim 20, wherein said internal circuit further comprises a driver unit.

22. The method of claim 21, wherein amplification of voltage could be defined by said driver unit.

23. The method of claim 21, wherein period of voltage could be defined by said driver unit.

24. The method of claim 19, wherein said automatic test equipment further comprises a signal channel, which is a signal I/O and is connected with said measuring-assistant module.

25. The method of claim 19, wherein said measuring-assistant module further comprises a device which could be charged and discharged.

26. The method of claim 25, wherein said device comprises a capacitance.

27. The method of claim 26, wherein said capacitance is a constant which is known.

28. A method for measuring accurate stray capacitance of automatic test equipment, comprising:
an automatic test equipment having an internal circuit and a driver unit is provided, wherein said internal circuit could be charged and discharged by said driver unit several times and electricity of said internal circuit could be normalized;
discharging steps of said automatic test equipment are performed, and said steps comprise:
(a) said internal circuit is charged and discharged several times by said driver unit;
(b) values of voltage from V1 to V2;
(c) interval of self-discharge is measured; and
(d) said interval of self-discharge is substituted into mathematical expression of R-C discharge, and a first R-C equation is obtained;
a measuring-assistant module is provided to connect with said automatic test equipment;
discharging steps (a)˜(d) are repeated and a second R-C equation is obtained; and
stray capacitance of said automatic test equipment is obtained by solving said first and second R-C equations.

29. The method of claim 28, wherein amplification of voltage could be defined by said driver unit.

30. The method of claim 28, wherein period of voltage could be defined by said driver unit.

31. The method of claim 28, wherein said measuring-assistant module further comprises a device which could be charged and discharged.

32. The method of claim 29, wherein said device comprises a capacitance.

33. The method of claim 32, wherein said capacitance is a constant which is known.

34. The method of claim 28, wherein said automatic test equipment further comprises a signal channel, which is a signal I/O and is used to connect said driver unit with said measuring-assistant module.
